(19) United States
(12) Patent Application Publication
(10) Pub. No.: US 2015/0282354 A1
(43) Pub. Date: Oct. 1, 2015

(54) MULTI VIEWING ANGLE PORTABLE ELECTRONIC DEVICE SUPPORT

(71) Applicant: Logitech Europe S.A., Lausanne (CH)

(72) Inventors: Malachy Spollen, Lausanne (CH); Li-Jen Chien, Zhubei City (TW); Chia Feng Lee, Taichung City (TW); Ming Sung Ku, Keelung City (TW)

(21) Appl. No.: 14/674,439

(22) Filed: Mar. 31, 2015

Related U.S. Application Data
(60) Provisional application No. 61/973,700, filed on Apr. 1, 2014.

(51) Int. Cl. H05K 5/02; A45C 11/00; A45C 13/00; H05K 5/03

(52) U.S. Cl. CPC H05K 5/0226; H05K 5/0234; H05K 5/03; A45C 11/00; A45C 13/005; A45C 2011/002; A45C 2011/003

(57) ABSTRACT

Certain embodiments of the invention include a double hinge for an electronic device case, with hinge stoppers integrally formed to prevent rotation beyond 180 degrees. Certain embodiments include a hinge comprising a first hinge plate, a second hinge plate, and a third hinge plate, where the first hinge plate is adapted to be pivotally engaged with the second hinge plate through the third hinge plate. The first and second hinge plates include two shaft bushings coaxially disposed and facing each other at confronting sides, and the third hinge plate comprises two shaft bushings on two opposite sides so that to coaxially dispose each shaft bushing of the third hinge plate with the shaft bushing respectively of the first and second hinge plate.

### CROSS-REFERENCES TO RELATED APPLICATIONS

This application is a nonprovisional of and claims the benefit of priority of U.S. Provisional Application No. 61/973,700, entitled, “Multi Viewing Angle Portable Electronic Device Support,” filed on Apr. 1, 2014, which is herein incorporated by reference in its entirety for all purposes.

### TECHNICAL FIELD

Embodiments of the present invention relate to the field of portable electronic device support, and more specifically to a portable electronic device support able to be arranged in various configurations to provide multiple viewing angles.

### BACKGROUND

A portable electronic device, such as a tablet computer or smart phone, often uses a case for protection or support. Some portable electronic device cases are classical and provide only a cover or shell function, which can provide protection. Other portable electronic device cases provide for holding or support in different configurations or multiple viewing angles.

Cases for electronic devices can use hinges for connecting front and back covers of a case. U.S. Pub. No. 20130094131 an example using double hinge, with detents for locking, for a tablet case. Hinges, such as double hinges, are also used with the electronic devices themselves, although the designs vary due to the different requirements for a device versus a case. For example, U.S. Pub. 20110099756 shows a double hinge so a tablet can fold more than 270 degrees so a user can hold it in one hand. U.S. Pat. No. 8,746,645 shows a double hinge with a stop to prevent over-rotation, for a laptop riser.

### BRIEF SUMMARY

In one embodiment of the invention, a double hinge for a case is provided with stoppers that prevent the case from opening more than 180 degrees. This is particularly advantageous for a case with a cloth cover, where bending beyond 180 degrees can ruin the fabric by stretching it too much. The stoppers can be formed integrally with mating pieces of the hinge assembly, to lower manufacturing costs. The hinge design provides a hinge with a flat profile that provides minimal dissension of the fabric and provides a smoother appearance.

According to certain embodiments of the invention, a hinge includes a first hinge plate, a second hinge plate, and a third hinge plate, where the first hinge plate is adapted to be pivotally engaged with the second hinge plate through the third hinge plate. The first and second hinge plates can include two shaft bushings coaxially disposed and facing each other at confronting sides. The third hinge plate can include two shaft bushings on two opposite sides so that to coaxially dispose each shaft bushing of the third hinge plate with the shaft bushing respectively of the first and second hinge plate.

In some embodiments, a cut out section is formed in each shaft bushing of the first and second hinge plates, and each shaft bushing of the third hinge plate comprises two projections forming stoppers so that each cut out section of the shaft bushings of the first and second hinge plates are able to receive a stopper of each shaft bushing section of the third hinge plate. The hinge plates can made from a flat metal material or other suitable materials, as would be appreciated by one of ordinary skill in the art.

In further embodiments, each of the first and second hinge plates can have a width of 20 mm and a length of 30 mm, with confronting sides 30 mm long and being at a distance of 6 mm. In an exemplary embodiment, the first and second hinge members can be made of a stainless steel material having a thickness of 0.5 mm, having a force in a single axis comprised between 1.5 and 2.5 kgf and a force decay of 20%. Furthermore, the first and the second hinge plates can include screw apertures.

In certain embodiments, the first plate includes a first cavity section and a second cavity section, where the second plate includes a first cavity section and a second cavity section, where the first cavity sections of the first and second plate are adapted to receive respectively the first and second hinge plates of the hinge, and where the second cavity sections of the first and second plate being adapted to respectively receive a first and second fixing plate. The first and the second plates can include a cut out section on the border adapted to receive the confronting sides respectively of the first and second hinge plates. In some implementations, the fixing plates can be aluminum, and the first and second plates are plastic.

In some embodiments, a portable electronic device support includes a frame, and a base including a front side and a rear side, the rear side having a hinge line. The hinge line can have a hinge structure that includes a first hinge plate, a second hinge plate, and a third hinge plate, where the first hinge plate is adapted to be pivotally engaged with the second hinge plate through the third hinge plate, where the hinge line is configured to allow the positioning of the frame at a predetermined angle, where the structure is integrated on the rear side of the tablet cover case, and where the first plate and the second plate of the hinge structure are disposed on both sides of the hinge line.

In further embodiments, a method for manufacturing a hinge having first, second, and third hinge plates is described herein, where the first hinge plate adapted to be pivotally engaged with the second hinge plate through the third hinge plate, the first and second hinge plates having two shaft bushing sections on one side, at each extremity of confronting sides, and the third hinge plate having two shaft bushing sections, on both sides of the third hinge plate. The method including forming four projections on the third hinge, where two projections being respectively formed on each shaft bushing section, curling the shaft bushing sections into a substantially cylindrical shape, and adapting the projections of each shaft bushing to cooperate with the cut out sections of the shaft bushings of the first and second hinges respectively.

In certain embodiments, a method for manufacturing a hinge having first, second, and third hinge plates is described herein, where the first hinge plate adapted to be pivotally engaged with the second hinge plate through the third hinge plate, the first and second hinge plates having two shaft bushing sections on one side, at each extremity of confronting sides, and the third hinge plate having two shaft bushing sections, on both sides of the third hinge plate. The method can include cutting out material from each shaft bushing section of the first and second hinge plate so as to form a projection on each shaft bushing section. The method can further include curling the shaft bushing sections of the hinge plate members so as to form the shaft bushings, assembling the hinge plates by disposing the shaft bushings respectively of the first, second and third hinges coaxially disposed with each other, the shaft bushings of the third hinge being disposed between the shaft bushings of the first and second hinges. In some cases, the method includes inserting a shaft through the shaft bushings respectively at each confronting side of the first and second hinges.

In some implementations, the method can further include inserting screws through the first plate of the first hinge with screws through corresponding apertures formed in the first hinge, and disposing the first hinge member in the first cavity section of the first plate prior to inserting the screws through the first plate of the first hinge. Some embodiments can include disposing the first fixing plate in the second cavity section on the first hinge plate and inserting screws through the second plate of the second plate through corresponding apertures formed in the second hinge.

The invention is now described, by way of example, with reference to the accompanying drawings. The specific nature of the following description should not be construed as limiting in any way the broad nature of this summary.

### BRIEF DESCRIPTION OF THE DRAWINGS

In order that the manner in which the above recited and other advantages and features of the invention are obtained, a more particular description of the invention briefly described above will be rendered by reference. Notwithstanding any other forms that may fall within the scope of the present invention, preferred forms of the invention will now be described, by way of example only, with reference to the accompanying drawing in which:

FIG. 1 schematically shows a view of a portable electronic device support, according to certain embodiments the invention;

FIG. 2 schematically shows a view of a portable electronic device support, according to certain embodiments of the invention;

FIG. 3 schematically shows a view of the processing steps for providing a hinge, according to certain embodiments of the invention;

FIG. 4 schematically shows a view of the hinge of FIG. 3 in a flat position;

FIG. 5 schematically shows a view of the hinge of FIG. 3 at a viewing angle;

FIG. 6 schematically shows a perspective view of a hinge structure at a particular stage of manufacture, according to certain embodiments of the invention;

FIG. 7 schematically shows a perspective view of a hinge structure at a particular stage of manufacture, according to certain embodiments of the invention;

FIG. 8 schematically shows a perspective view of a hinge structure at a particular stage of manufacture, according to certain embodiments of the invention;

FIG. 9 schematically shows a view of a hinge structure, according to certain embodiments of the invention;

FIG. 10 is a diagram of an exploded view of an embodiment of the invention showing the stoppers as formed integrally with the hinge.

FIG. 11 schematically shows a view of a portable electronic device support, according to certain embodiments the invention;

FIG. 12 schematically shows a view of a portable electronic device support, according to certain embodiments of the invention; and

FIG. 13 schematically shows a view of the processing steps for providing a hinge, according to certain embodiments of the invention.

### DETAILED DESCRIPTION

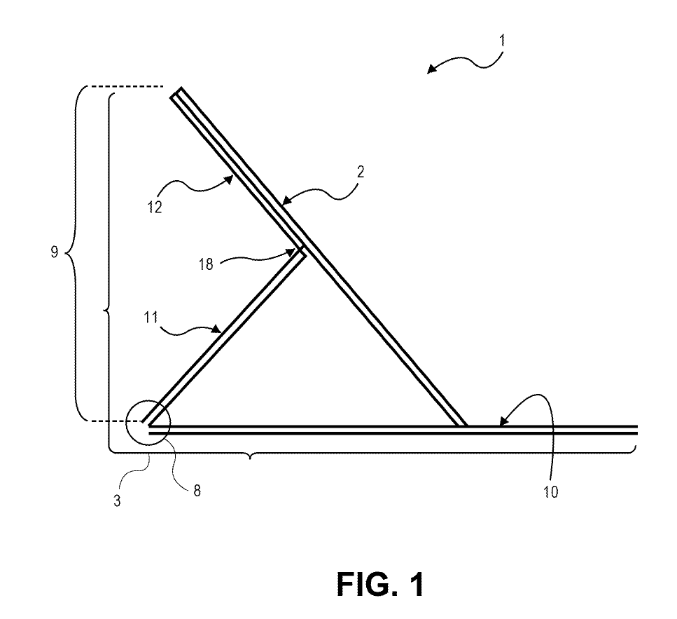

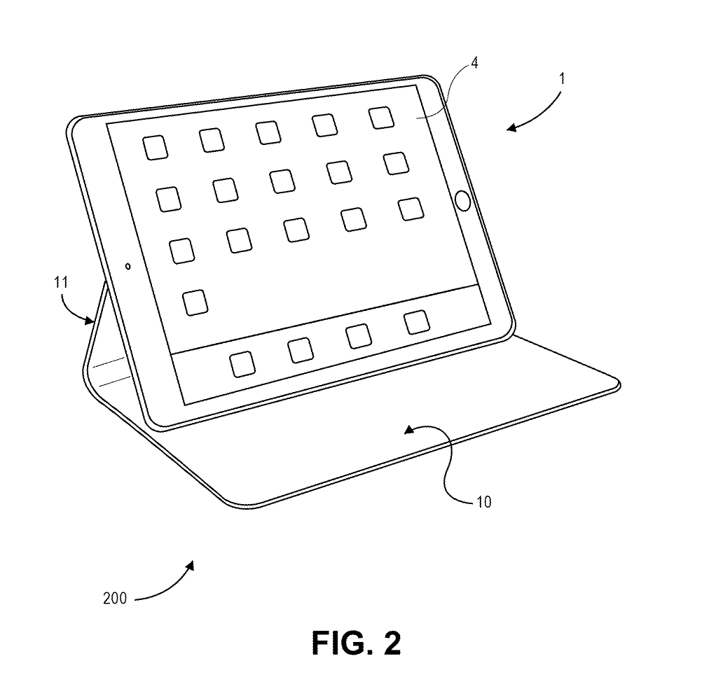

As shown in FIG. 1 and FIG. 2, a portable electronic device support 1 comprises a frame 2 and a base (support) 3. The base 3 comprises a front 10 side and a rear side 9. The rear side 9 further comprises a lower rear portion 11 and an upper rear portion 12. The frame 2 is adapted to surround an attachable and detachable electronic device 4, such as a tablet as represented in FIG. 2. The frame 2 and upper rear portion 12 are pivotally coupled to the lower rear side 11 of the base 3. The rear side 9 of base 3 is pivotally coupled to the front side 10 of base 3 along pivot line 8. The rear side 9 of the base 3 further comprises a pivot line 18, coupling the lower rear portion 11 and upper rear portion 12. In some embodiments, pivot line 8 can be a hinge, similar to pivot line 18, a non-stiff hinge, or a flexible piece of material that is configurable such that the front of the base 10 and the rear of the base 9 can be adjusted and set at different angles relative to each other.

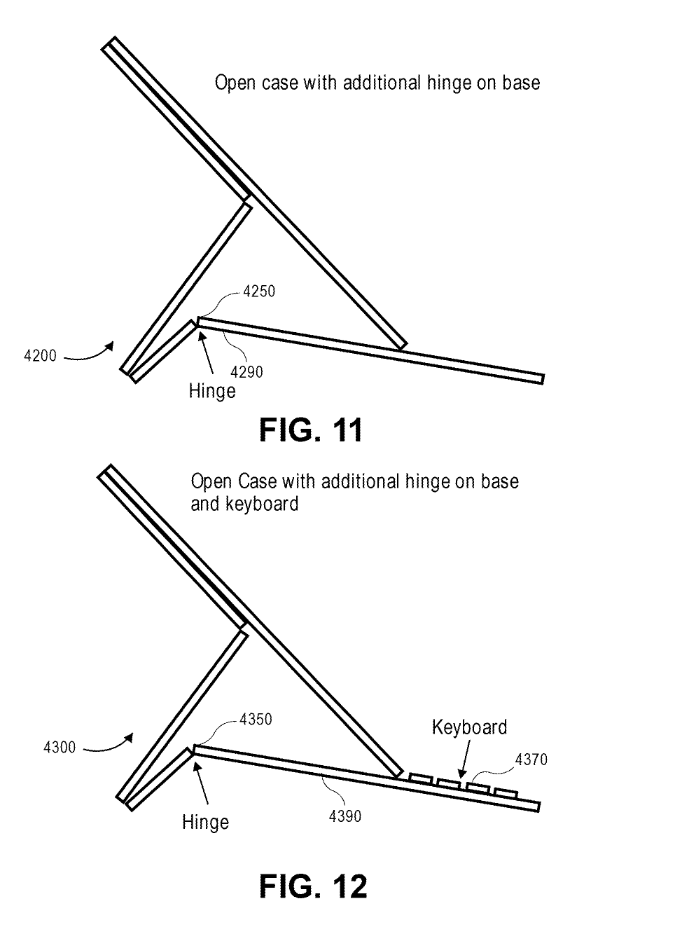

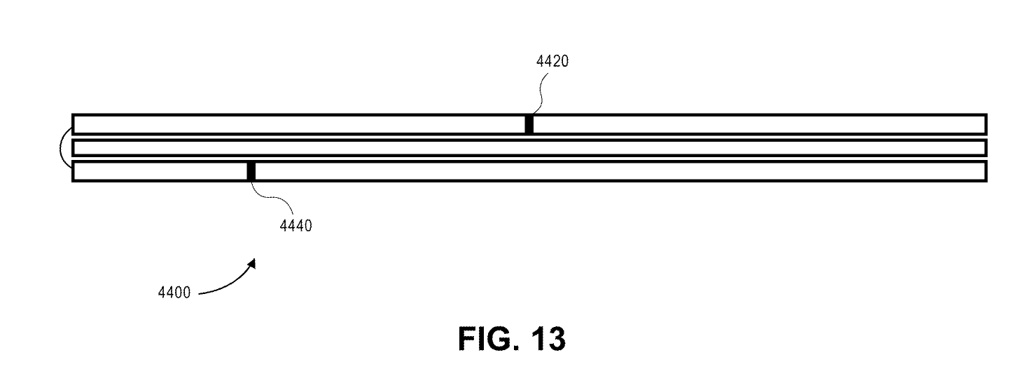

FIGS. 11 and 12 schematically show views of portable electronic device supports 4200, 4300, according to certain embodiments the invention. FIG. 12 includes a keyboard 4370 disposed thereon. Both embodiments are similar to FIG. 1 in that they include a portable electronic device support with a frame and base. The frame is adapted to surround an attachable and detachable electronic device 4, such as a tablet as represented in FIG. 2. Another similarity includes the frame and upper rear portion being pivotally coupled to the lower rear side of the base 4290, 4390. The base of both device supports 4200 and 4300 includes an additional hinge 4250, 4350 configured to provide additional support configurations. For example, FIGS. 11 and 12 show the front side of the base propped up at an angle to provide the user with different viewing angles and/or different keyboard angles to accommodate different ergonomic needs and provide, e.g., better typing angles. The hinge can be configured in any suitable angle. In some embodiments, hinge 4250, 4350 can be a stiff hinge that can support the weight of the device support without collapsing onto itself. Alternatively, other types of hinge structures can be used, such as a non-stiff hinge, a flexible material, or the like. FIG. 13 schematically shows a view of a portable electronic device supports 4400 in a closed configuration, according to certain embodiments of the invention. Support 4400 shows, in particular, support 4200 folded in a portable configuration with pivot line 4420 (corresponding to 18 in FIG. 1) and pivot line 4440 with hinge 4250 (not shown).

According to some embodiments, a switch can be incorporated into one or more of the hinge structures described herein. For example, opening or closing a hinge could turn a switch on or off, or there may be multiple modes of operation depending on the position of the hinge. Switches can be used to turn the device supports on (first position) or off (second position). For example, opening the device support (e.g., changing from the configuration shown in FIG. 13 to FIG. 11) may trigger a switch disposed at or near pivot line 4420 or 4440 to turn the device support on. Switches can also be used in conjunction with a local processor to turn on the electronic device (i.e., tablet computer) via wireless communication (e.g., Bluetooth communication). Some switches may have additional positions in addition to a bimodal on/off state that can perform other functions. For example, some switches may activate media only keys, turn on an associated touch pad, turn on the keyboard, switch between keyboard-only and touch pad-only operation, and the like. Hinges can include a single switch or multiple switches. Switches can be implemented at a single hinge or multiple hinges.

Certain embodiments may only include a base portion with (or without) a keyboard 4370. The base portion can include a hinge 4350 and pivot line operable to configure the base in a number of different configurations. For transport, the keyboard/base would be flat, and in use a user could bend the back portion at the pivot line/hinge to give the base an inverted “v” shape, as shown in FIG. 12, for a customizable typing angle. A switch can be disposed in the hinge to turn on/off the keyboard 4370 when the hinge is rotated (e.g., from a flat base configuration to an inverted v-shape configuration, as shown in FIG. 12).

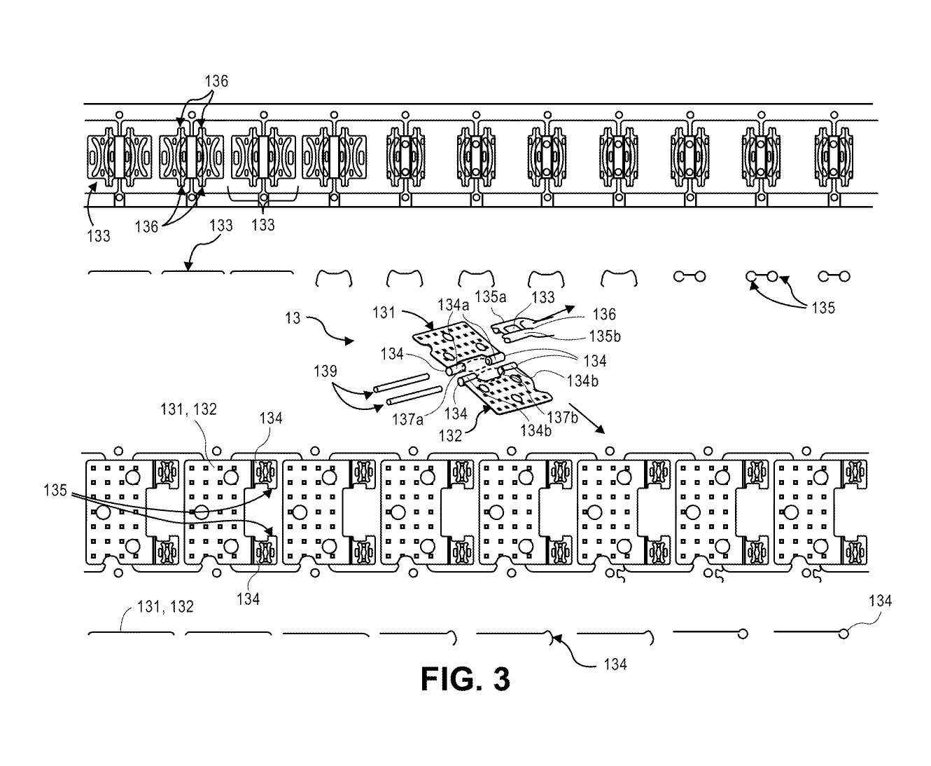

FIG. 3 schematically shows a view of the processing steps for providing a hinge for a device support, according to certain embodiments of the invention. Hinge 13 is located at the pivot line 18 and allows for the adjustment of the angle of the frame 2 relative to the lower rear side 11. A hinge 13 can also be added at hinge line 8, which would allow for altering the angle between the lower rear base 11 and the front base 10 (or support surface).

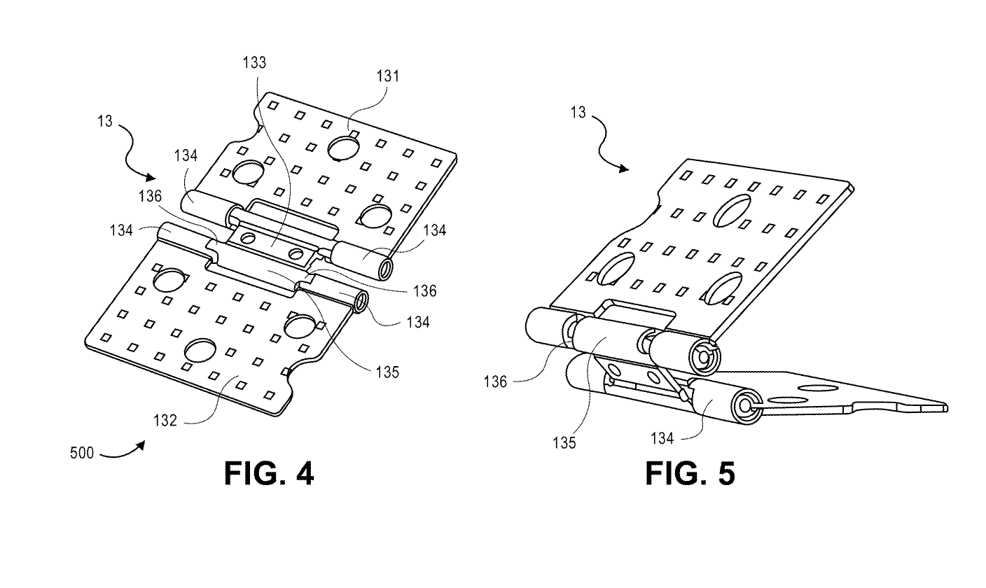

As shown in FIG. 4, the hinge 13 comprises two plates 131, 132. A first hinge plate 131 is adapted to be pivotally engaged with a second hinge plate 132. The first and second hinge plates 131, 132 are formed from a generally flat material, for example made of stainless steel.

As represented in the figures, in an embodiment of the invention, the first and second hinge plate members 131, 132 comprise shaft bushings 134a and 134b (or knuckles) coaxially disposed and facing each other wherein the shaft bushings 134 are located at confronting sides and more precisely on each extremity of the confronting sides of the first and second hinge plate 131,132.

The hinge 13 also comprises a third hinge plate 133, also formed from a generally flat plate. The first and second hinge plates 131, 132 are coupled via the third hinge plate 133. The third hinge plate 133 comprises two shaft bushings sections on two opposite sides of the third hinge plate 133 so as to form two shaft bushings 135a, 135b to be coaxially disposed with the shaft bushings 134a, 134b respectively.

The third hinge plate 133 also comprises four projections or stoppers 136: two projections 136 are respectively formed on each shaft bushing section so that the projections 136 of each shaft bushing 135a, 135b are adapted to cooperate with cut out sections 137a, 137b of the shaft bushings 134a, 134b of the first and second hinge plates 131,132 respectively. The stoppers or projections 136 advantageously control the folding angle and prevent the portable electronic device support 1 from flatting after being folded over and back. The stoppers or projections 136 prevent the portable electronic device support from further opening after a predetermined maximum angle as fixed by the dimensions of the cut out sections 137a, 137b and the projections 135a, 135b of the shaft bushings 134a, 134b. This predetermined angle corresponds to a working angle position wherein an electronic device mounted in the portable electronic device support is in a flat position. The first and second hinge plates 131,132 being generally parallel with the hinge plate 133 when the hinge 13 is in the fully open position, and the first and second hinge plates 132a,132b being generally perpendicular to the third hinge plate 133 when the hinge is in the fully closed position. The relative angles of the hinge plates in the closed position may be altered or defined by the configuration of the projections or stoppers 136 and the cutout sections 137a,137b. When in the fully closed position, the lower portion 11 of the base 3 may then be disposed onto the front side 10 of the base 3. One extreme position of the hinge 13 in a flat position is for example shown in FIG. 4. An intermediary closed position of the hinge 13 is shown in FIG. 5.

A method for providing such hinge 13 is represented in FIG. 3, comprising a step of forming the first and second hinge plates 131, 132, each having two shaft bushing sections on one side of a flat plate, at each extremity of the confronting sides. It will be well understood that the first and second hinge plates may be manufactured in a similar process. In the figures, a rotation of the first hinge plate 131 by 180-degrees provides the second hinge 132 and vice versa. In embodiments of the invention the dimensions and layouts of the two hinge plates may be different from what is shown in the figures, or different from each other without deviating from the scope of the invention. By having the hinge plates being generally the same, efficiencies in manufacturing can be achieved. Each shaft bushing section 134a,134b comprises a cut out section 137a, 137b so as to form the projection or stopper 135 on each shaft bushing section.

When the hinge plates 131,132 are being formed from a generally flat piece of material, the shaft bushing sections 134a, 134b are adapted to form the shaft bushings after a curling step. In the curling step, the flat shaft bushing sections are formed into substantially cylindrical shapes as represented in the progression of images illustrated in FIG. 3. FIG. 3 illustrates a top and side view of a representative hinge place (such as 131,132) having the hinge shaft bushing formed. In an embodiment of the invention the formation step of the shaft bushing may occur in one step, or in a series of discrete steps. Further, a single or multiple hinge shaft bushings may be formed in the same step, or in different steps.

FIG. 3 also illustrates a similar shaft bushing curling step performed on the third hinge plate 133. The shaft bushings 135a, 135b may be formed at the same time, or separately. Further, the shaft bushings 135a, 135b may be formed in a single step, or in multiple discrete steps.

Once the shaft bushings 134a, 134b and 135a, 135b are formed, the shaft bushings 134a, 134b and 135a, 135b are coaxially aligned and shafts 139 are inserted through the shaft bushings. The hinge 13 has then a dual axis along two shafts 139. Mating portions of the shafts and shaft bushings may be configured to have defined frictional properties. For example, the mating portions may be configured to have relatively low friction, providing little resistance to rotation. Alternately, the mating portions may be configured to have relatively high friction, providing significant resistance to rotation. In an embodiment of the invention by configuring a relatively high level of friction between the shafts and shaft bushings, the portable electronic device support shall be able to support a mounted electronic portable device in multiple positions, relying at least partially on the stiffness of the hinge to maintain the position of the portable electronic device. In embodiments of the invention different portions of the shafts and shaft bushings may have different levels of friction. In further embodiments of the invention, the levels of friction between the shafts and shaft bushings may be different depending on the direction of rotation. For example, a hinge may be configured to rotate clockwise with a resistance force of X, and to rotate counterclockwise with a resistance force of Y. According to embodiments of the invention, the resistance forces X and Y may be different. One of ordinary skill in the art will recognize that there are a number of ways to vary resistance based on the direction of rotation. By creating a hinge with different levels or resistance to rotation in one direction verses another, a portable electronic device support according to the invention can be made to fold “easier” in one direction than another. For example, it may be desirable to increase the resistance required to open the hinge from the flat position to the rotated over position. Consider the portable electronic device support as illustrated in FIG. 1 and FIG. 2. The portable electronic device support 1 may be configured to resist being folded about the hinge line 18. For example, if a user touches or pushes the icons on the top row of the mounted portable electronic device in normal use, the portable electronic device support would not further rotate about the hinge line 18. In such an example, as illustrated in FIG. 1, the rotational resistance to counterclockwise rotation about hinge line 18 would be relatively high. Continuing the example, the rotational resistance about the hinge line 18 may be configured to be relatively lower in the clockwise direction. If a user touches or pushes on the bottom row of icons on the portable electronic device, there will be resistance from both the hinge at hinge line 18 and the interface between the frame 2 and the front side 10 of base 3.

In an embodiment of the invention where the rotational resistance about hinge line 18 is different in the clockwise and counterclockwise direction, a portable electronic device support can be configured to provide sufficient stability to resist rotating about hinge line 18 in normal use, and be “easier” to increase the angle of the frame 2 relative to the front side 10 of the base 3, or potentially even to close the portable electronic device support so that a mounted portable electronic device is covered on both its front and back by the portable electronic device support.

In embodiments of the invention the hinge 13 may be comprised of more than three plates. Additional plates may be arranged along the axis of the shafts. Further, additional plates may be added to create additional rotational axis between the plates 131, 132. If additional rotational axis are added, more complex arrangements of stoppers and rotational resistance may be configured. For example, it may be relatively easy to open the portable electronic device support and rotate the frame out to a specific angle relative to the front side 10 of the base 3, and the rotating resistance may increase to rotate any further. This would allow for relative ease in opening and closing the portable electronic device support, but also provide sufficient resistance and stability when in normal use.

In an embodiment of the invention, each hinge plate 131,132 has a width of 20 mm and a length of 30 mm. The confronting sides are for example 30 mm long and at a distance of 6 mm. The centers of the dual axis along the shafts 139 are then at a distance of 6 mm from each other. The plates used for forming the hinge plates 131, 132, 133 are made of stainless steel and have a thickness of 0.5 mm. A force in a single axis is comprised between 1.5 and 2.5 kgf. The hinge has advantageously a force decay of 20%.

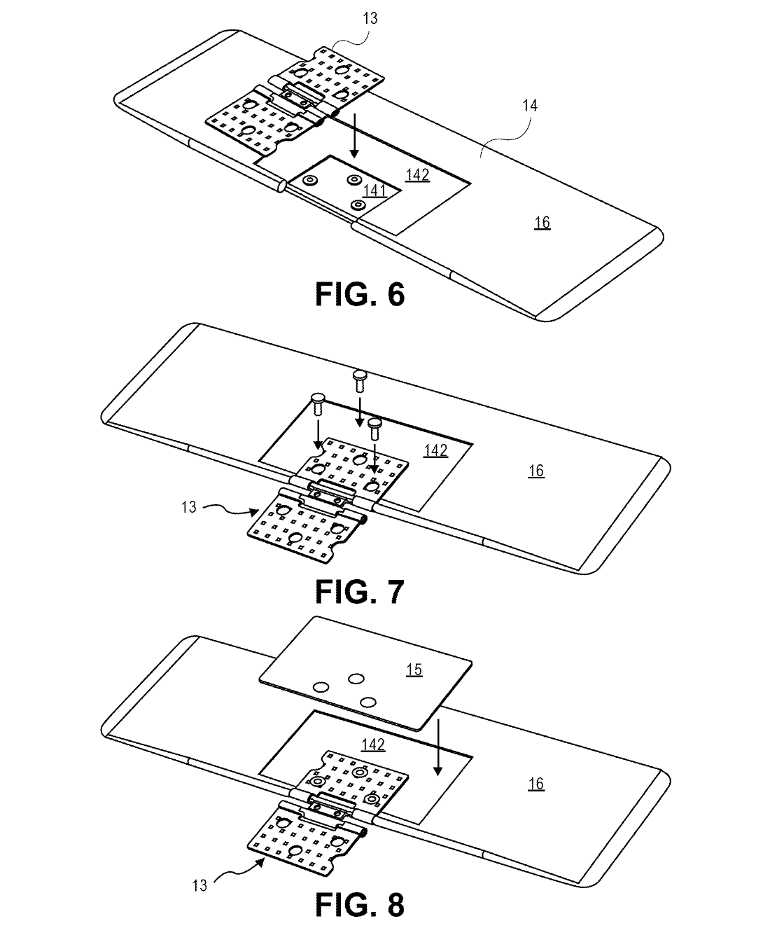

The first hinge plate 131 comprises screw apertures for affixing to a first plate 14 in plastic, as shown on FIG. 6. The first plate 14 comprises a first cavity section 141 and second cavity section 142.

The first cavity section 141 is adapted to receive the first hinge plate 131. The first cavity 141 allows an easier positioning of the first hinge plate member 131 on the first plate 14. The hinge plate is first stuck or glued with the first plate 14. The screws provides advantageously enough attachment force, while thanks to the adhesive, the force applied on the hinge is evenly absorbed. It will be understood that any other suitable adhesive means is possible.

As represented in FIG. 7, the first hinge plate may be fixed with screws through the corresponding apertures formed within the first hinge plate 131. The first plate 14 may also comprise a cut out section on its border adapted to receive the confronting side of the first hinge plate 131.

As shown in FIG. 8, the first hinge plate 131 and the cavity section 142 provide a flat surface adapted to receive a fixing plate 15. In the following the fixing plate is a rectangular plate.

The fixing rectangular and flat plate 15 also comprises apertures so that when the fixing rectangular plate 15 is positioned within the cavity section 142 formed in the first plate 14, the screws used to fix the first hinge plate 131 with the first plate 14 are disposed in front of the apertures of the fixing rectangular plate 15. The second cavity 142 allows an easier positioning of the 15.

The fixing rectangular plate 15 may be aluminum and fixed to the first plate 14, which may be plastic, with an adhesive to secure the first hinge plate 131. It also provides a smooth surface of the first plate 14 in its entire surface before the final fixation with the portable electronic device support 1.

The hinge 13 can be securely positioned by the plastic plates 14,16 and the rectangular plate 15. The first and second hinge plates 131, 132, as fixed between the plastic plates 14, 16 from one side and the rectangular plates 15 from another side, prevents the hinge 13 from moving or being removed easily from its initial position. The hinge structure maintains the rotation of the rear side of the base about the hinge line 18.

It will be well understood that the materials or fixations are non-limiting examples and any other way to fix the different elements for providing the same advantages which prevents the hinge 13 or the first and second hinge plates 131, 132 from being easily removed from the upper rear portion 12 of the base 3 of the portable electronic device support.

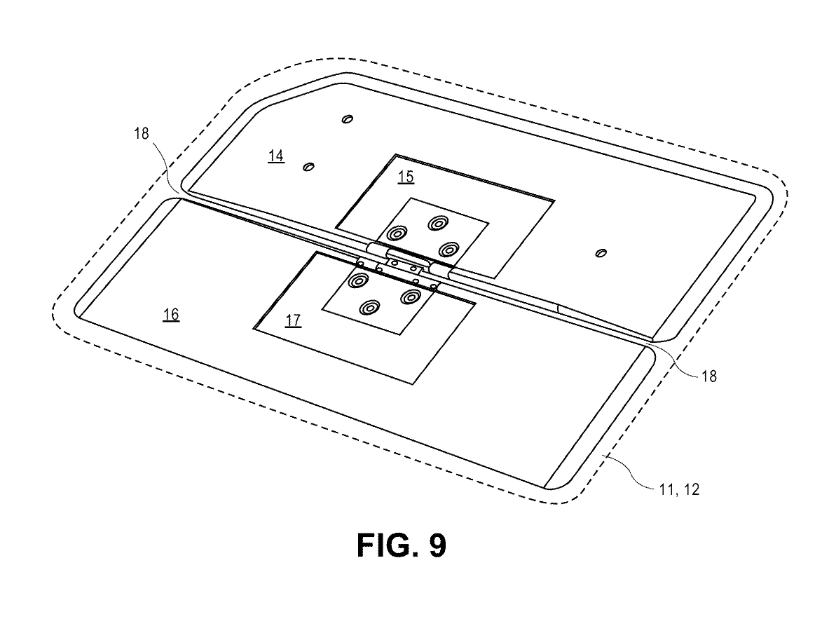

The second hinge plate 132 is fixed with a similar manner to a second plate 16 similar to the first plate 14 as shown in FIG. 9.

The second plate 16 comprises a first and second cavity (not represented) adapted to respectively receive the second hinge plate 132 and a second plate 17 similar to the first plate 15.

The first plate 14 and the second plate 16 are then pivotally coupled through the hinge 13. The two plates pivot with respect to each other along the axis of the hinge line 18.

This final structure 13, 14, 15, 16, 17 is then integrated into a cover, for example rear side of base 3. The first and the second plate 14, 16 may have similar dimensions to the rear side 11, 12 of the portable electronic device support 1 so that a user or holder does not feel the presence of the hinge 13, the rear side 11, 12 having the ability to be a smooth surface.

In a preferred embodiment the hinge 13 is located in the middle of the rear side 11, 12, the hinge line 18 being positioned between the first and second plastic plates 14, 16.

It will be well understood that the number of hinges, the forms and dimensions of the plates are non-limited example. Other embodiments are possible. Other means for fixing the different plates may be used.

Any other form or dimension either of the hinge 13, or the hinge structure 13,14,15,16 may be used according to the size or form of the portable electronic device support itself, and also for example depending on the force to be applied for positioning at multiple viewing angles. For example, in order to get a bigger force, the diameter of the shaft bushes 134, 135 may be increased. The number of hinges 13 may be increased either with same dimensions or with lower dimensions. The hinge line 18 may be not positioned in the middle of the rear side. The first and second plates 14, 16 and the fixing plates 15 are dimensioned accordingly with cavity sections 141, 142 adapted to the used hinges 13 and to the used plates 15.

Various options may be employed to covers or hide the rear side and the hinge structures as described herein. Any suitable process as known in the art may be used.

In embodiments of the invention a very flat rear side of the base can be formed. By having a very flat rear side of the base (i.e. no significant bump from the hinge protruding above the planar top/bottom of the surface) a cosmetically appealing portable electronic device support. By eliminating or significantly reducing any protrusion of the hinge about the surface, in embodiments of the invention the frame that holds a portable electronic device can be mounted directly adjacent to the rear side of the base. This enables a thinner overall thickness to the portable electronic device support. The hinge construction and layout according to embodiments of the invention allow for a very thin rear base surface, also enabling a thinner overall thickness to the portable electronic device support. Inventions that provide a reduction in the overall thickness of a portable electronic device support can provide significant advantages in marketing and selling consumer products.

In embodiments of the invention, a hinge similar to hinge 13 may be positioned at other locations on a portable electronic device support. For example, a similar hinge may be positioned at pivot line 8. In embodiments of the invention there may be a hinge similar to hinge 13 at pivot line 8 and pivot line 18, or at only one of pivot lines 8 and 18. Further, in embodiments of the invention a portable electronic device support may have a different configuration than that shown in FIG. 1 and FIG. 2, but could still employ a hinge similar to hinge 13.

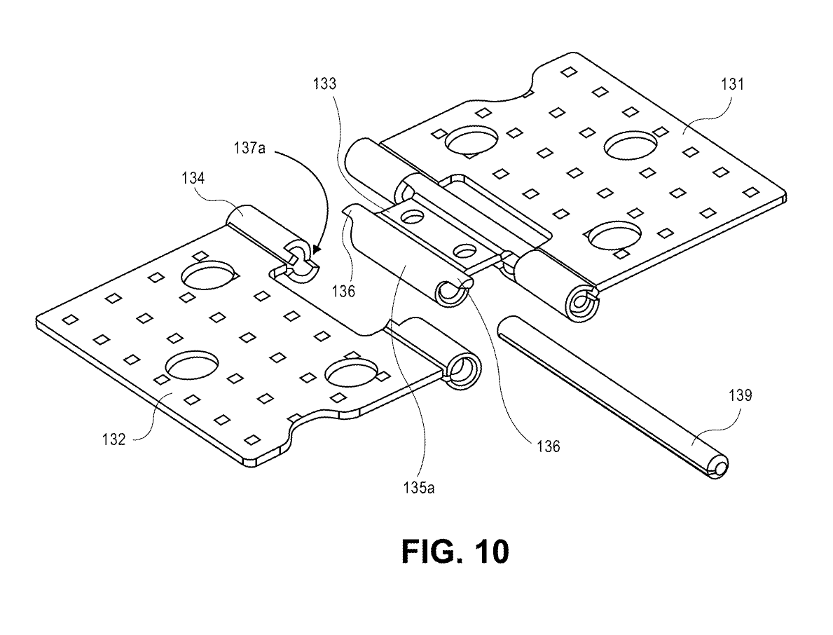

FIG. 10 is an exploded diagram of one embodiment of the hinge structure, more clearing showing the stopper structure. Hinge plates 131 and 132 have integrally formed shaft bushings 134. A cut-out section 137a of bushing 134 provides the end points for engaging a stopper 136, to prevent rotation beyond 180 degrees. As shown, the stoppers 136 are integrally formed with the shaft bushing 135a of the middle, third hinge plate 133. A shaft 139 is inserted through the shaft bushings to assemble the hinge. In an alternate embodiment, the stopper 136 could be formed as part of the shaft bushings 134 on hinge plates 131, 132, and cut-out sections 137a could be formed as part of the shaft bushing 135a of the third, middle hinge plate 133.

Thanks to the invention, the hinge structure coupled to the rear side of a portable electronic device support is configured to allow a frame to pivot from a first position to a second position so that the frame or an electronic device mounted in the frame stands at a viewing angle suitable for a user. The portable electronic device support provides an easy and fast multiple angle viewing function wherein an electronic device mounted in the frame is able to stand at an angle as desired by the user. Embodiments of the invention may be employed in a portable electronic device support with one or more preset viewing angles, or in a portable electronic device support that allows a user to select the desired angle from the range of angular positions enabled by the hinge. In some embodiments, there is no need to provide grooves for facilitating the stand of an electronic device inserted into the frame of the portable electronic device support.

It will be well understood that such portable electronic device support is also suitable for any other portable electronic device, such as a mobile phone, notebook, etc. Further, a fixed device, such as a display, may be mounted within the support and remain within the scope of the invention.

What is claimed is:

1. A case for an electronic device, the case having top and bottom covers connected by a hinge, the hinge comprising:
a first hinge plate;
a second hinge plate; and
a third hinge plate, wherein the first hinge plate is adapted to be pivotally engaged with the second hinge plate through the third hinge plate;
wherein one of the first and second hinge plates, and the third hinge plate, comprise two shaft bushings coaxially disposed and facing each other at confronting sides, and
wherein the other of the third hinge plate, and the first and second hinge plates, comprises two shaft bushings on two opposite sides so that to coaxially dispose each shaft bushing of the third hinge plate with the shaft bushing respectively of the first and second hinge plate;
wherein a cut out section is formed in a shaft bushing of one of the first and second hinge plates, and the third hinge plate, and a shaft bushing of the other of the first and second hinge plates, and the third hinge plate, comprises at least one projection forming a stopper so that the cut out section receive a stopper to prevent rotation beyond a predetermined angle.

2. The case of claim 1 further comprising a fabric material covering at least portions of the top and bottom covers and the hinge.

3. The case of claim 2, wherein a cut out section is formed in each shaft bushing of the first and second hinge plates, and each shaft bushing of the third hinge plate comprises two projections forming stoppers so that each cut out section of the shaft bushings of the first and second hinge plates are able to receive a stopper of each shaft bushing section of the third hinge plate.

4. The case of claim 1 wherein the hinge plates are made from a flat metal material.

5. The case of claim 1 wherein each first and second hinge plates has a width of 20 mm and a length of 30 mm, with confronting sides having 30 mm long and being at a distance of 6 mm, said first and second hinge members being made of a stainless steel material having a thickness of 0.5 mm, having a force in a single axis comprised between 1.5 and 2.5 kgf and a force decay of 20%.

6. The case of claim 1 wherein the first and the second hinge plates comprises screw apertures.

7. The case of claim 1, wherein the first plate includes a first cavity section and a second cavity section, wherein the second plate includes a first cavity section and a second cavity section, wherein the first cavity sections of the first and second plate are adapted to receive respectively the first and second hinge plates of the hinge, and wherein the second cavity sections of the first and second plate being adapted to respectively receive a first and second fixing plate.

8. The case of claim 7, wherein the first and the second plates comprises a cut out section on the border adapted to receive the confronting sides respectively of the first and second hinge plates.

9. The case of claim 7, wherein the fixing plates are aluminum, and the first and second plates are plastic.

10. A portable electronic device support comprising:
a frame;
a fabric cover over the frame; and
a base including a front side and a rear side, the rear side having a hinge line that includes a hinge structure comprising:
a first hinge plate;
a second hinge plate; and
a third hinge plate,
wherein one of the first and second hinge plates, and the third hinge plate, comprise two shaft bushings coaxially disposed and facing each other at confronting sides, and
wherein the other of the third hinge plate, and the first and second hinge plates, comprises two shaft bushings on two opposite sides so that to coaxially dispose each shaft bushing of the third hinge plate with the shaft bushing respectively of the first and second hinge plate;
wherein a cut out section is formed in a shaft bushing of one of the first and second hinge plates, and the third hinge plate, and a shaft bushing of the other of the first and second hinge plates, and the third hinge plate, comprises at least one projection forming a stopper so that the cut out section receive a stopper to prevent rotation beyond an angle of 180 degrees;
wherein the first hinge plate is adapted to be pivotally engaged with the second hinge plate through the third hinge plate, wherein the hinge line is configured to allow the positioning of the frame at a predetermined angle, wherein the structure is integrated on the rear side of the tablet cover case, and wherein the first plate and the second plate of the hinge structure are disposed on both sides of the hinge line.

11. The support of claim 10 wherein a cut out section is formed in each shaft bushing of the first and second hinge plates, and each shaft bushing of the third hinge plate comprises two projections forming stoppers so that each cut out section of the shaft bushings of the first and second hinge plates are able to receive a stopper of each shaft bushing section of the third hinge plate.

12. The support of claim wherein the hinge plates are made from a flat metal material.

13. The support of claim 10 wherein each first and second hinge plates has a width of 20 mm and a length of 30 mm, with confronting sides having 30 mm long and being at a distance of 6 mm, said first and second hinge members being made of a stainless steel material having a thickness of 0.5 mm, having a force in a single axis comprised between 1.5 and 2.5 kgf and a force decay of 20%.

14. The support of claim 10 wherein the first and the second hinge plates comprises screw apertures.

15. The support of claim 10 wherein the first plate includes a first cavity section and a second cavity section, wherein the second plate includes a first cavity section and a second cavity section, wherein the first cavity sections of the first and second plate are adapted to receive respectively the first and second hinge plates of the hinge, and wherein the second cavity sections of the first and second plate being adapted to respectively receive a first and second fixing plate.

16. The support of claim 15 wherein the first and the second plates comprises a cut out section on the border adapted to receive the confronting sides respectively of the first and second hinge plates.

17. The support of claim 15 wherein the fixing plates are aluminum, and the first and second plates are plastic.

18. The support of claim 10, wherein the frame is configured to support a tablet, and includes walls on one part of the frame positioned to tightly engage the sides of the tablet.

19. The support of claim 10 further comprising:
screws inserted through the second plate of the second plate through corresponding apertures formed in the second hinge.

20. A portable electronic device support comprising:
a frame;
a fabric cover over the frame; and
a base including a front side and a rear side, the rear side having a hinge line that includes a hinge structure comprising:
a first hinge plate;
a second hinge plate; and
a third hinge plate,
wherein one of the first and second hinge plates, and the third hinge plate, comprise two shaft bushings coaxially disposed and facing each other at confronting sides, and
wherein the other of the third hinge plate, and the first and second hinge plates, comprises two shaft bushings on two opposite sides so that to coaxially dispose each shaft bushing of the third hinge plate with the shaft bushing respectively of the first and second hinge plate;
wherein a cut out section is formed in a shaft bushing of one of the first and second hinge plates, and the third hinge plate, and a shaft bushing of the other of the first and second hinge plates, and the third hinge plate, comprises at least one projection forming a stopper so that the cut out section receive a stopper to prevent rotation beyond an angle of 180 degrees;
wherein the first hinge plate is adapted to be pivotally engaged with the second hinge plate through the third hinge plate, wherein the hinge line is configured to allow the positioning of the frame at a predetermined angle, wherein the structure is integrated on the rear side of the tablet cover case, and wherein the first plate and the second plate of the hinge structure are disposed on both sides of the hinge line;
wherein a cut out section is formed in each shaft bushing of the first and second hinge plates, and each shaft bushing of the third hinge plate comprises two projections forming stoppers so that each cut out section of the shaft bushings of the first and second hinge plates are able to receive a stopper of each shaft bushing section of the third hinge plate;
wherein the hinge plates are made from a flat metal material;
wherein the first plate includes a first cavity section and a second cavity section, wherein the second plate includes a first cavity section and a second cavity section, wherein the first cavity sections of the first and second plate are adapted to receive respectively the first and second hinge plates of the hinge, and wherein the second cavity sections of the first and second plate being adapted to respectively receive a first and second fixing plate;
wherein the first and the second plates comprises a cut out section on the border adapted to receive the confronting sides respectively of the first and second hinge plates.
